(19) United States
(12) Patent Application Publication
(10) Pub. No.: US 2026/0182345 A1
(43) Pub. Date: Jun. 25, 2026

(54) 3D Integrated Circuit Device

(71) Applicant: IMEC VZW, Leuven (BE)

(72) Inventors: Prashant Dubey, Cambridgeshire (BE); Priya Venugopal, Linden (BE); Ivick Guerra Gomez, Madrid (ES); Odysseas Zografos, Kessel-Lo (BE)

(21) Appl. No.: 19/423,938

(22) Filed: Dec. 17, 2025

(30) Foreign Application Priority Data
Dec. 20, 2024 (EP) 24222390.7

(51) Int. Cl. H10W 20/43; H10D 80/30; H10W 20/41; H10W 90/26

(52) U.S. Cl. CPC H10W 20/43; H10D 80/30; H10W 20/427; H10W 90/26

(57) ABSTRACT

A device includes a first device tier including a first set of active devices and a second device tier including a second set of active devices. The device also includes a clocked circuit including first active devices of the first set of active devices, and a clock distribution network including a plurality of clock signal routing interconnects arranged in an interconnect structure arranged at a side of the first device tier facing the second device tier. The device also includes a set of active clock devices formed by second active devices of the second set of active devices. The clocked circuit is connected to the clock distribution network to receive a clock signal.

### CROSS-REFERENCE TO RELATED APPLICATIONS

The present application is a non-provisional patent application claiming priority to European Patent Application No. 24222390.7, filed on Dec. 20, 2024, the contents of which are hereby incorporated by reference.

### FIELD OF THE DISCLOSURE

The present disclosure generally relates to a 3D integrated circuit device.

### BACKGROUND

Clock distribution is an important consideration in the design of integrated circuit (IC) devices including synchronous circuits.

A common implementation of a clock distribution network is a clock tree, such as an H-tree. The cumulative wire length of a clock tree of a typical state-of-the-art IC may be relatively long, for instance spanning more than 200 mm for a 1 mm² portion of a die, where a greater number of sink nodes along the clock distribution network tends to be associated with increased wire lengths.

A conventional approach for clock distribution is to route the clock signal at the frontside of the die of the IC device, i.e., using the back-end-of-line (BEOL) interconnect structure on the frontside of the die (“frontside interconnect structure”). More recently, IC designs where the clock signal instead is routed using a BEOL interconnect structure on the backside of the die (“backside interconnect structure”) have been proposed.

A benefit of backside routing of the clock signal is that competition for routing resources in the frontside interconnect structure (which also are needed for routing non-clock signals) may be reduced.

### SUMMARY

While there are benefits to backside routing of the clock signal, it may also introduce additional challenges in the circuit design. For instance, there is an area penalty associated with connecting the clock signal between the backside and the active devices on the frontside, which increases in proportion to the number of times the signal is routed between the backside and the frontside. Moreover, given the trend in the industry to incorporate the power delivery network (PDN) in the backside interconnect structure (a backside PDN), the backside interconnect structure may typically comprise metal layers with relatively wide and closely spaced metal lines for power rails. This may limit the available space on the backside for contacts for routing the clock signal to the frontside. Therefore, a large number of connections between the clock signal and the backside and the frontside may necessitate less dense metal layers for power routing and/or breaking the continuity of the power rails, which both may be degrade the performance of the PDN.

In view of the above, it is a potential benefit of the disclosure to provide improved approaches for designing IC devices to allow backside routing of the clock signal with less area penalty. Further, it is a potential benefit of the disclosure to provide improved approaches for designing IC devices to allow backside routing of the clock signal while requiring smaller number of connections of the clock signal between the backside and frontside. Further and alternative potential benefits may be appreciated from the following.

According to an aspect of the present disclosure, there is provided a 3D IC device comprising:
a first semiconductor device tier comprising a first set of active devices;
a second semiconductor device tier comprising a second set of active devices;
a clocked circuit comprising first active devices comprised in the first set of active devices of the first semiconductor device tier; and
a clock distribution network comprising a plurality of clock signal routing interconnects arranged in an interconnect structure arranged at a side of the first semiconductor device tier facing the second semiconductor device tier, and a set of active clock devices formed by second active devices comprised in the second set of active devices of the second semiconductor device tier;
wherein the clocked circuit is connected to the clock distribution network to receive a clock signal.

The 3D IC device is based, at least in part, on the insight that by arranging the active devices (i.e., transistors) of active clock devices of the clock distribution network in a second semiconductor device tier, a more area-efficient implementation of the connections between the clock distribution network and the clocked circuit, and thus a more area-efficient clocked circuit and IC device, may be realized. In particular, arranging the active devices (second active devices) of the active clock devices in the second semiconductor device tier allows reducing a number of connections between the clock distribution network and the first semiconductor device tier, compared to had the transistors of the active clock devices, as is conventionally done, been arranged in the first semiconductor device tier. Hence, fewer contacts are needed for routing the clock signal from the side of the first semiconductor device tier facing the second semiconductor device tier (the “second side of the first semiconductor device tier”) through the first semiconductor device tier, to the opposite side of the first semiconductor device tier (the “first side of the first semiconductor device tier”).

Moreover, by arranging the second active devices of the active clocked devices in the second semiconductor device tier, the footprint occupied in the first semiconductor device tier by active devices of the clock distribution network may be reduced. This may also simplify the design process, by allowing a more flexible placement of the active clock devices in the second semiconductor device tier.

That is, the active clock devices may be provided at the locations within the second semiconductor device tier where they confer a greatest benefit to the performance of the clock distribution network (e.g., skew optimization), with less regard to the layout of the first semiconductor device tier. For instance, some of the second active devices may be arranged within a footprint of circuit blocks implemented by active devices of the first semiconductor device tier, such as registers or self-contained circuit blocks such as macros, IP blocks, or non-IP block. Hence, the layout of the active clock devices may be determined more freely than had the active clock devices been implemented by the active devices of the first semiconductor device tier.

In the present disclosure, the term “active clock device” may refer to any transistor-based device of the clock distribution network, such as a clock driver, a clock repeater, a clock gate, or a clock buffer (non-inverting or inverting).

While the configuration of the active clock devices according to the first aspect may be useful for all of the aforementioned types of active clock devices, it may be especially useful when applied to clock buffers. That is, specifically arranging the active devices (i.e., transistors) of the clock buffers in the second semiconductor device tier may facilitate clock tree balancing (e.g., for the purpose of skew optimization), as the locations of the clock buffers may be determined more flexibly, for the aforementioned reasons. This allows clock buffers to be arranged close to registers implemented by the first semiconductor device tier, with less area penalty. Additionally, the active devices of the clock buffers may be placed within the footprint of self-contained circuit blocks of the afore-mentioned types.

Accordingly, in some embodiments, the set of active clock devices comprises one or more active clock devices located within a footprint of a circuit block being any one of a register, a macro, an IP block, or a non-IP block, and comprising active devices of the first set of active devices of the first semiconductor device tier.

In some embodiments, the clocked circuit comprises a set of clock inputs, each connected to an output of a respective active clock device (e.g., a respective clock buffer) of the set of active clock devices to receive the clock signal from the clock distribution network.

In some embodiments, the clocked circuit comprises a set of registers, wherein the set of clock inputs comprises clock inputs of the set of registers. Hence, registers of the clocked circuit may be connected to outputs of the active clock device (e.g., outputs of clock buffers) implemented by active devices of the second semiconductor device tier.

In some embodiments, the registers comprise flip-flops and/or latches. The present disclosure is hence applicable to both edge-triggered registers (flip-flops) and level-triggered registers (latches).

In some embodiments, the clock distribution network is a clock tree. The clock distribution network may thus be realized using one or more relatively sparsely populated metal layers of the interconnect structure.

As may be appreciated, the “first side” and the “second side” of the first semiconductor device tier may in the present disclosure refer respectively to a frontside and a backside of the first semiconductor device tier. For example, in some embodiments, the first set of active devices of the first semiconductor device tier is comprised in a first front-end-of-line (FEOL) structure of a first die of the 3D IC, wherein the first set of active devices are arranged at a first side (“frontside”) of the first die, and wherein the interconnect structure comprising the plurality of clock signal routing interconnects and the second semiconductor device tier are arranged at a second side (“backside”) of the first die, opposite the first side of the first die. That is, the interconnect structure comprising the clock signal routing interconnects and the second semiconductor device tier comprising the active devices of the active clock devices may each be arranged at the backside of the first die.

In some embodiments, the second set of active devices of the second semiconductor device tier is comprised in a second FEOL structure of a second die of the 3D IC device. The second set of active devices may be arranged either at a side of the second die facing the first semiconductor device tier (“first side of the second die”), or at a side of the second die facing away from the first semiconductor device tier (“second side of the second die”).

Alternatively, in some embodiments, the second set of active devices are backend transistors arranged in the interconnect structure comprising the plurality of clock signal routing interconnects. In the present disclosure, the term “backend transistors” refers to BEOL-compatible transistors, i.e., transistors which may be fabricated in a BEOL-compatible process (e.g., in a low/BEOL-compatible thermal budget). For instance, the backend transistors may be thin-film transistors (TFTs) such as carbon nanotube (CNT) field-effect transistors (FETs), 2D channel FETs, or oxide-semiconductor FETs.

In some embodiments, the 3D IC device further comprises a power distribution network (PDN) arranged in the interconnect structure comprising the plurality of clock signal routing interconnects, and configured to supply power to the clocked circuit and the clock distribution network. The interconnect structure may thus provide a double-function of clock distribution and power distribution. Hence, the interconnect structure may distribute power to the active devices of the first and second semiconductor device tiers (in particular to the first and second active devices of the registers and any active clock devices), and distribute the clock signal to the second active devices of the registers and any active clock devices.

In some embodiments, the 3D IC device further comprises a first interconnect structure arranged at a side of the first semiconductor device tier facing away from the second semiconductor device tier (i.e., the first side of the first semiconductor device tier) and configured to interconnect the first set of active devices. Hence, the first set of active devices, including the first active devices of the clocked circuit, may be interconnected by the first interconnect structure. As the clock signal routing interconnects (and optionally the PDN) are arranged in the interconnect structure at the opposite second side of the first semiconductor device tier, the first set of active devices may be interconnected with less competition for routing resources with the clock distribution network (or PDN).

In some embodiments, the interconnect structure comprising the plurality of clock signal routing interconnects is a second interconnect structure and is arranged at a side of the second semiconductor device tier facing the first semiconductor device tier (i.e., the first side of the second semiconductor device tier). The second interconnect structure may thus be arranged between the first and second semiconductor device tiers. The second interconnect structure may thus provide routing resources both for the first and second semiconductor device tiers. In particular, where the second interconnect structure comprises a PDN, power distribution to the first and second semiconductor device tiers may be facilitated.

In embodiments where the first and second side of the first semiconductor device tier refer, respectively, to the frontside and backside of the first semiconductor device tier, the first interconnect structure may refer to a frontside interconnect structure arranged at (e.g., on) the frontside of the first semiconductor device tier. Correspondingly, the second interconnect structure may refer to a backside interconnect structure arranged at the backside of the first semiconductor device tier.

In embodiments where the first semiconductor device tier is comprised in a first die and the first set of active devices, the first interconnect structure may refer to a frontside interconnect structure arranged at (e.g., on) the frontside of the first die, and the second interconnect structure may refer to a backside interconnect structure arranged at (e.g., on) the backside of the first die.

In some embodiments, the interconnect structure comprising the plurality of clock signal routing interconnects is a second interconnect structure and is arranged at a side of the second semiconductor device tier facing away from the first semiconductor device tier (i.e., the second side of the second semiconductor device tier). Thus, the clock signals may also be routed at the second side of the second semiconductor device tier (which in some embodiments may correspond to the backside of the second semiconductor device tier or, as the case may be, a second die comprising the second semiconductor device tier). In embodiments where the second interconnect structure further comprises a PDN, this applies correspondingly to the power distribution.

The 3D IC device may further comprise a third interconnect structure arranged at the side of the second semiconductor device tier facing the first semiconductor device tier (i.e., the first side of the second semiconductor device tier) and configured to interconnect the second set of active devices. Hence, the second set of active devices, including the active devices of the active clock devices, may be interconnected by the third interconnect structure at the first side (e.g., frontside) of the second semiconductor device tier. As the clock signal routing interconnects (and optionally the PDN) are arranged in the second interconnect structure at the opposite second side (e.g., backside) of the second semiconductor device tier, the second set of active devices may be interconnected with less competition for routing resources with the clock distribution network (and PDN).

The principles of the present disclosure are also applicable to multi-tier IC designs comprising more than two semiconductor device tiers.

Hence, in some embodiments, the 3D IC device further comprises a third semiconductor device tier comprising a third set of active devices, wherein the clocked circuit is a first clocked circuit, and the 3D IC device further comprises a second clocked circuit comprising third active devices comprised in the third set of active devices of the third semiconductor device tier, and wherein the second clocked circuit is connected to the clock distribution network to receive a clock signal.

Hence, the second semiconductor device tier may be used to implement the active clock devices of a clock distribution network shared between the first and second clocked circuits.

In some embodiments, the second clocked circuit comprises a set of clock inputs each connected to an output of a respective active clock device of the set of active clock devices to receive the clock signal from the clock distribution network.

### BRIEF DESCRIPTION OF THE FIGURES

The above, as well as additional, features will be better understood through the following illustrative and non-limiting detailed description of example embodiments, with reference to the appended drawings.

FIG. 1 schematically shows a cross-section of a 3D IC device, according to an example.

FIG. 2 is a schematic block diagram of a circuit configuration of the 3D IC device of FIG. 1, according to an example.

FIG. 3a shows a schematic perspective view of the 3D IC device of FIG. 2, according to an example.

FIG. 3b shows a distribution of clock buffers and registers between first and second circuit tiers, according to an example.

FIG. 4 schematically shows a cross-section of a further 3D IC device, according to an example.

FIG. 5 is a schematic block diagram of a circuit configuration of the 3D IC device of FIG. 4, according to an example.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

Example embodiments of a 3D integrated circuit (IC) or 3D IC device will in the below be described with reference to the drawings. The drawings are only schematic and the relative dimensions of some structures and layers may be exaggerated and not drawn to scale. Rather the dimensions may be adapted for illustrational clarity and to facilitate understanding. When present in the figures, the indicated axes X and Y consistently refer to a horizontal direction and a vertical direction, respectively. As used herein, the term “horizontal” refers to a direction parallel to a main plane of extension of a device tier, a die, or substrate of the 3D IC. The term “vertical” refers to a direction parallel to a normal direction to the main plane of extension of a device tier, die, or substrate, i.e., transverse to the horizontal direction. In other words, “horizontal” and “vertical” refer respectively to in-plane and out-of-plane directions with respect to a device tier, die, or substrate. In the present disclosure, when an element (e.g. a die or other structure) is referred to as being “on” another element, it can be directly on the other element or on one or more intermediate elements on the other element. Conversely, when an element is referred to as being “directly on” another element, there is no intermediate element and the element is thus formed in physical contact or abutment with the other element. In the present disclosure, when two elements are said to be “connected” or “interconnected” it is meant that the elements are electrically connected or coupled, directly or via one or more intermediate conductive structures (e.g., interconnects), unless stated otherwise.

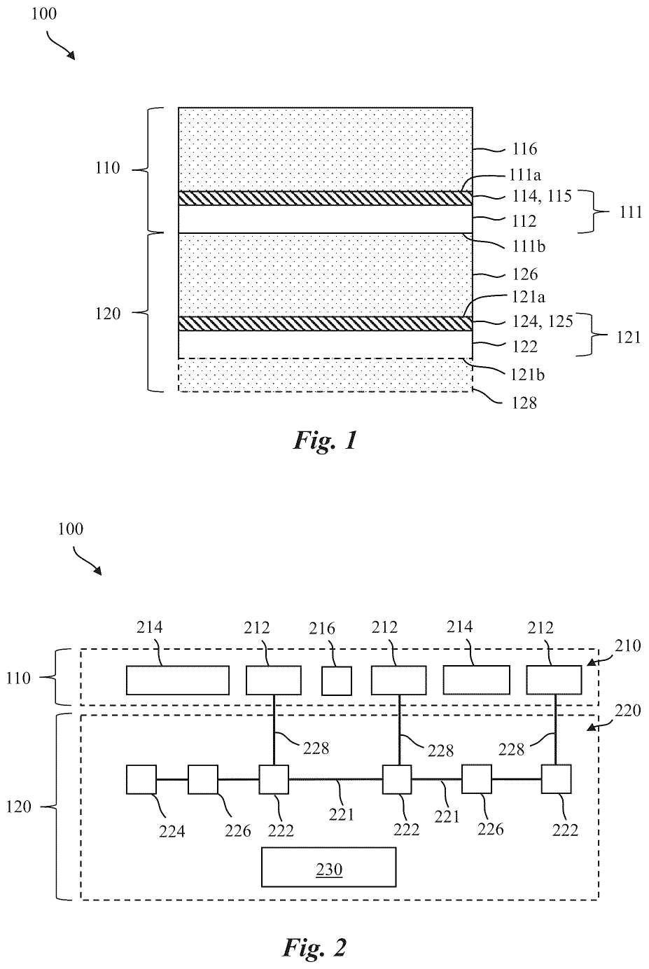

FIG. 1 shows a schematic cross-section of a 3D IC device 100 in accordance with some embodiments of the present disclosure. The IC device 100 comprises a stack of circuit tiers including a first circuit tier 110 and a second circuit tier 120. The first circuit tier 110 is stacked on top of, i.e., arranged above, the second circuit tier 120, as seen along the Y direction. While FIG. 1 shows the first circuit tier 110 and the second circuit tier 120, the circuit tiers may more generally be two circuit tiers of a plurality of stacked circuit tiers. As further described in the following, the first circuit tier 110 and the second circuit tier 120 may in some implementations correspond to first and second dies, respectively, of a stack of dies.

The first circuit tier 110 comprises a first device tier 111 (“semiconductor device tier”). The second circuit tier 120 comprises a second device tier 121. The first circuit tier 110 comprises a first set of active devices 115. The second circuit tier 120 comprises a second set of active devices 125. The first device tier 111 may, as indicated in FIG. 1, comprise a substrate 112 and a front-end-of-line (FEOL) structure 114 arranged or formed on the substrate 112 and comprising the first set of active devices 115. The first set of active devices 115 may thus be referred to as frontend transistors of the FEOL structure 114. The second device tier 121 may have a corresponding structure, and thus comprise a substrate 122 (corresponding to the substrate 112) and a FEOL structure 124 (corresponding to the FEOL structure 114) arranged or formed on the substrate 122 and comprising the second set of active devices 125. The second set of active devices 125 may thus be referred to as frontend transistors of the FEOL structure 124. The substrate 112 and the substrate 122 may each be a conventional semiconductor substrate, suitable for CMOS circuits and semiconductor device processing, for instance, a semiconductor substrate of Si, Ge, or SiGe. Other non-limiting examples include a silicon-on-insulator (SOI) substrate, a GeOI substrate, or a SiGeOI substrate. The term “FEOL structure” can mean a layer, tier, or vertical section of an IC device comprising an active semiconductor layer (i.e., comprising the active regions or patterns of the active devices/transistors) and a gate layer (i.e., comprising the gates of the active devices). The active regions may comprise source/drain (S/D) regions and channel regions of the active devices. The FEOL structure may further comprise a local contact or interconnect layer (i.e., comprising the source/drain (S/D) contacts of the active devices). While referred to as a single layer, the local contact layer may typically comprise (at least) two metal layers: a bottom layer (“contact-to-active” or “trench silicide”) and a top or “plug” layer (e.g. of TiN, Co, Ru, and/or W). The active devices of the FEOL structure may comprise NMOSFETs and PMOSFETs, for instance, realized as horizontal channel FETs, such as FinFETs, nanosheet FETs, or nanowire FETs. The active semiconductor layer may be formed by semiconductors such as Si, Ge, or SiGe, or other bulk/3D semiconductors conventionally used to realize CMOS devices. The active semiconductor layer may be formed on a substrate, or in a thickness portion of a substrate, e.g. the substrate 112 or the substrate 122 in the depicted example.

The IC device 100 further comprises a first interconnect structure 116 and a second interconnect structure 126, e.g., a back-end-of-line (BEOL) interconnect structure. The term “BEOL interconnect structure” (or simply “interconnect structure”) can mean a vertical stack of interconnect layers, each comprising interconnects, (typically of metal) such as horizontally routed interconnects (conductive traces or lines) or vertically routed interconnects (“vias”), embedded in interlayer dielectrics. An interconnect layer of horizontally routed interconnects may be referred to as a “metal routing layer” (or simply a “routing layer”). An interconnect layer of vertically routed interconnects may be referred to as a via layer. A via layer may thus provide vertical routing of signals between different metal routing layers, or between a routing layer and conductive elements of the FEOL structure (e.g., gates or S/D contacts).

The first interconnect structure 116 is arranged at a first side 111a of the first device tier 111. The first side 111a is as shown the side of the first device tier 111 facing away from the second device tier 121. The second interconnect structure 126 is arranged at a second side 111b of the first device tier 111. The second side 111b is as shown the opposite side of the first device tier 111 facing the second device tier 121. The second interconnect structure 126 is thus arranged between the first device tier 111 and the second device tiers 121. In the illustrated example, the first side 111a defines a frontside of the FEOL structure 114 and the first device tier 111 whereas the second side 111b defines a backside of the FEOL structure 114 and the first device tier 111. Thus, with respect to the FEOL structure 114 and the first device tier 111, the first interconnect structure 116 may be referred to as a (first) frontside interconnect structure and the second interconnect structure 126 may be referred to as a backside interconnect structure.

In FIG. 1, the first device tier 111 and the first interconnect structure 116 are shown to be comprised in the first circuit tier 110, while the second device tier 121 and the second interconnect structure 126 are shown to be comprised in the second circuit tier 120. In some implementations, the illustrated partitioning of the IC device 100 into the first circuit tier 110 and the second circuit tier 120 may correspond to an actual structural and/or manufacturing-related partitioning of the IC device 100. For example, where the IC device 100 comprises a stack of dies, the first circuit tier 110 and the second circuit tier 120 may correspond respectively to a first and a second die. In the present disclosure, the term “die” is used to refer to a die structure or chip of an IC device. Thus, the first device tier 111 (e.g., comprising the substrate 112 and the FEOL structure 114) may be a device tier of the first die, and the first interconnect structure 116 may be a frontside interconnect structure of the first die. Correspondingly, the second device tier 121 (e.g., comprising the substrate 122 and the FEOL structure 124) may be a device tier of the second die, and the second interconnect structure 126 may be a frontside interconnect structure of the second die. The first circuit tier 110 and the second circuit tier 120 may be fabricated and subsequently be stacked and bonded with the second interconnect structure 126 facing the second side 111b of the first die (i.e., face-to-back). Thus, while the second interconnect structure 126 in this example is fabricated at a frontside of the second die, it may after stacking and bonding define a backside interconnect structure, with respect to the first die. The stack of dies may be formed using any one of die-to-die bonding, wafer-to-die bonding, or wafer-to-wafer bonding.

In a further example, a first portion (i.e., a first subset of interconnect layers) of the second interconnect structure 126 may be formed during backside processing of the first die/wafer and a second portion (i.e., a second subset of interconnect layers) of the second interconnect structure 126 may be formed during frontside processing of the second die/wafer. In this case, the second interconnect structure 126 may be formed during bonding of the first and second dies/wafers, by bonding the first and second portions of the second interconnect structure 126, thereby forming a common/composite second interconnect structure defining the second interconnect structure 126 with respect to the first die. As another example, the second interconnect structure 126 may be exclusively formed during backside processing of the first die/wafer and subsequently the first and second dies may be bonded with the second interconnect structure 126 to the second device tier 121 of the second die.

Furthermore, in the illustrated example, the first device tier 111 includes a substrate 112 and the second device tier 121 includes a substrate 122. However, it is possible to perform substrate or wafer thinning during device fabrication, to provide access to the active devices (e.g., source/drain contacts) from a backside. Thus, prior to bonding, the substrate 112 and the substrate 122 may be thinned. In case of extreme substrate thinning, the substrate(s) may be substantially removed such that only the FEOL structure 114 or the FEOL structure 124 remains in the finished IC device 100. Thus, the substrate 112 and the substrate 122 shown in FIG. 1 may in some implementations be regarded as optional.

In a further unillustrated example, the first and second dies may be bonded back-to-back, such that the frontside 121a of the second device tier 121 faces away from the first device tier 111. In this case, the second interconnect structure 126 may in analogy with the above device fabrication examples be formed by: a backside interconnect structure of the second die/wafer formed exclusively during backside processing of the first die/wafer and subsequently bonded to the backside of the second die/wafer; a second portion of the second interconnect structure 126 formed during backside processing of the second die/wafer and a corresponding first portion of the second interconnect structure 126 formed during backside processing of the first die/wafer and subsequently bonded to the second portion; or a backside interconnect structure of the first die/wafer formed exclusively during backside processing of the first die/wafer and subsequently bonded to the backside of the second die/wafer.

In yet a further example, the second device tier 121 may be realized by backend transistors arranged in the second interconnect structure 126. Examples of backend transistors include TFTs, such as CNT FETs, and/or 2D channel FETs. A CNT FET is a transistor device comprising a channel structure of one or more CNTs. A 2D channel FET is a transistor device comprising a channel structure of a 2D semiconductor. Examples of 2D semiconductors include transition metal dichalcogenides (TMDs), IGZO, IGO, and other suitable 2D semiconductors conventionally used to realize backend transistors. The backend transistors may for example be formed during backside processing of the first die/wafer. Fabrication of backend transistors may comprise process techniques, such as deposition of channel material on top of an interconnect layer of a (BEOL) interconnect structure, patterning and doping the channel material to form channel regions and S/D regions, gate stack and S/D contact deposition, etc. After completing formation of the backend transistors, further interconnect layers may be processed on top of backend transistors, e.g., to form interconnects for the backend transistors and/or interconnects of a backside power distribution network (PDN), etc. Fabrication techniques which may be used to form the backend transistors include 3D sequential techniques (sometimes referred to as monolithic 3D integration) involving blanket active layer transfer onto a prefabricated FEOL structure and (a lower part of) an interconnect structure. In a monolithic 3D integration, the backend transistors can be fabricated at a low thermal budget to avoid degradation of the frontend transistors of the FEOL structure 114, typically below 500° C. Thus, backend transistors may be BEOL-compatible devices.

In each of the above-mentioned example implementations, the second interconnect structure 126 is arranged between the first device tier 111 and the second device tier 121 and may be referred to as a backside interconnect structure with respect to the first device tier 111 and first FEOL structure 114. Correspondingly, the second circuit tier 120 may be referred to as a backside circuit tier with respect to the first device tier 111 and the first circuit tier 110.

FIG. 2 is a schematic block diagram showing in a schematic manner a circuit configuration of the 3D IC device 100. As shown in FIG. 2, the IC device 100 comprises a clocked circuit 210 and a clock distribution network 220 connected to the clocked circuit 210. The clocked circuit 210 is comprised in the first circuit tier 110. The clock distribution network 220 is comprised in the second circuit tier 120. The clocked circuit 210 comprises a number of circuit portions such as the registers 212, the circuit blocks 214, and the circuit blocks 216, at least some of which are synchronous circuits clocked by the clock distribution network 220. Each of the registers 212, the circuit blocks 214, and the circuit blocks 216 comprise first active devices (transistors) comprised in the first set of active devices 115 of the first device tier 111. That is, the first active devices refer to any active devices/transistors (typically a subset) of the first device tier 111 (e.g., the first FEOL structure 114) comprised in the clocked circuit 210. For ease of explanation, the same reference signs may in the following be used to refer to respective circuit blocks of the clocked circuit 210 and the first active devices comprised in/implementing the respective circuit blocks.

The clock distribution network 220 comprises a set of active clock devices 222, 224, 226 formed by second active devices (transistors) comprised in the second set of active devices 125 of the second device tier 121. That is, the second active devices refer to any active devices/transistors (typically a subset) of the second set of active devices 125 (e.g., the second FEOL structure 124) comprised in the set of active clock devices. For ease of explanation, the same reference signs may in the following be used to refer to respective active clock devices of the clock distribution network 220 and the second active devices comprised in/implementing the respective active clock devices. The clock distribution network 220 further comprises a plurality of clock signal routing interconnects 221 arranged in the second interconnect structure 126, schematically indicated by the horizontally oriented lines. The clock signal routing interconnects 221 may be realized using a combination of routing layers and via layers of the second interconnect structure 126. The clock signal routing interconnects 221 further comprises inter-tier interconnects connected to the clocked circuit 210 of the first circuit tier 110 for vertically routing the clock signal between the first circuit tier 110 and the second circuit tier 120. The inter-tier interconnects 228 are in FIG. 2 schematically indicated by the vertically oriented lines. The specific implementation of inter-tier interconnects may depend on the device technology used to realize the IC device 100. For example, in the case of a 3D sequential fabrication process, the inter-tier interconnects may be implemented by a combination of horizontally-routed interconnects of one or more metal routing layers, vias of one or more via layers of the second interconnect structure 126, and inter-tier contacts. In the case of die/chip stacking, the inter-tier contacts may be implemented by backside contacts, or hybrid bond pads, i.e., bonded pads of the first and second dies. Where the first device tier 111 comprises a substrate 112, the inter-tier contacts may further comprise through-silicon vias (TSVs), extending through the substrate 112 and connected to the active devices 115 of the first FEOL structure 114. In the present disclosure, the term “TSV” refers to a via structure (i.e., a vertical electrical interconnect) extending through a substrate of a die, regardless of the type of semiconductor material of the substrate, consistent with its typical usage in the semiconductor industry.

The clock distribution network 220 may, for example, be implemented as a clock tree (e.g., an H-tree). However, other topologies are possible, such as a clock mesh, a clock spine, a clock fishbone, a serpentine architecture, or combinations thereof. The active clock devices of the clock distribution network 220 may include active clock devices 222, active clock devices 224, and/or active clock devices 226 such as clock drivers, clock repeaters, clock gates, clock dividers, clock multiplexers, and/or clock buffers (input/output buffers and balancing buffers). For example, the active clock devices 224 and the active clock devices 226 may represent any one of a clock driver, a clock repeater, a clock gate, a clock divider, a clock multiplexer, or a clock tree balancing buffer. Further, the the active clock devices 222 can be configured as a clock signal output connected to one or more corresponding clock signal inputs of the clocked circuit 210.

The clocked circuit 210 may comprise a set of clock inputs, each connected to an output of an active clock device 222 to receive the clock signal from the clock distribution network 220. Each clock input may be connected to a respective synchronous circuit portion or circuit block of the clocked circuit 210. The clocked circuit 210 may include various combinations of registers, macros, IP blocks, and/or non-IP blocks, each implemented by a subset of the first set of active devices 115 of the first device tier 111.

For example, a circuit block 214 may represent any one of a macro, an IP block, or a non-IP block. The circuit block 216 may represent some other logic circuit block, such as a combinational logic circuit block. Each register 212 may comprise flip-flops and/or latches. Each register 212 may comprise one or more clock inputs, each connected to a corresponding clock output of the clock distribution network 220. In particular, a clock input of a register 212 may as shown be connected to a clock output of an active clock device 222 of the clock distribution network 220. While not expressly shown in FIG. 2, the registers 212 may be connected to other circuit blocks 214 or circuit blocks 216 of the clocked circuit 210, to receive, store, and supply data processed by the clocked circuit 210.

As suggested by FIG. 2, a merit of implementing active clock devices 222, active clock devices 224, and/or active clock devices 226 in the second device tier 121 of the second circuit tier 120, is that the active clock devices may be placed flexibly, with less regard to the layout of the registers 212, the circuit blocks 214, and the circuit blocks 216 of the clocked circuit 210 of the first circuit tier 110. For instance, clock drivers, clock repeaters, clock gates, and/or clock buffers may be provided at the locations in the second circuit tier 120 where they confer a greatest benefit to the performance of the clock distribution network 220. In a conventional implementation of a backside clock distribution network, the active clock devices are implemented by active devices/transistors of the same device tier (e.g., of a same die) as the clocked/synchronous logic and memory circuits. Hence, the floorplan of the circuit needs to be designed such that there is space (e.g., die area) to accommodate the active clock devices alongside the logic and memory circuits. In contrast, since the first active devices 115 implementing the registers 212, the circuit blocks 214, and the circuit blocks 216 of the clocked circuit 210 and the second active devices 125 implementing the active clock devices 222, the active clock devices 224, and/or the active clock devices 226 are arranged in different circuit and device tiers, the active clock devices 222, the active clock devices 224, and/or the active clock devices 226 may be arranged within a footprint of the registers 212, the circuit blocks 214, and the circuit blocks 216 of the clocked circuit 210. A potential benefit applicable specifically to the active clock devices 222 is that the active clock devices 222 may be arranged close to connected registers 212, with less area penalty. More specifically, an active clock device 222 may as shown in FIG. 2 be arranged within the footprint of (e.g., be overlapped by) a connected register 212. The reduced area penalty follows from the active clock devices 222 not taking up any footprint in the first device tier 111, and further from fewer connections between the clock distribution network 220 and the first device tier 111 are needed compared to had the transistors of all of the active clock devices, as is in the conventional implementation, been arranged in the first device tier 111.

With further reference to FIG. 2, the clock distribution network 220 may be co-integrated with a power distribution network (PDN) 230 in the second circuit tier 120 and the second interconnect structure 126. The PDN 230 is in FIG. 2 indicated in a highly schematic manner, but may, as would be understood by the skilled person, comprise a plurality of power rails (e.g., VDD and VSS) in the backside interconnect structure, and be configured to supply power to the clocked circuit 210 and the clock distribution network 220. Consistent with denoting the second circuit tier 120 and the second interconnect structure 126 as a backside circuit tier and a backside interconnect structure, the PDN 230 may be referred to as a backside PDN, i.e., with respect to the first device tier 111 and the first circuit tier 110.

In addition to the interconnects of the second interconnect structure 126 discussed above (e.g., the clock signal routing interconnects 221, power rails of the PDN 230, etc.) the backside interconnect structure 126 further may comprise interconnects (e.g., in one or more metal routing and via layers) configured for signal routing between the second active devices 125 in the form of the active clock devices 222, the active clock devices 224, and/or the active clock devices 226. That is, the second interconnect structure 126 may be further configured to interconnect the second active devices 125, that is, the active clock devices 222, the active clock devices 224, and/or the active clock devices 226.

In the above discussion, reference has been made to the second interconnect structure 126 of the second circuit tier 120, wherein the second interconnect structure 126 comprises the clock signal routing interconnects 221 of the clock distribution network 220. However, as shown in FIG. 1, the second circuit tier 120 may comprise a further interconnect structure 128, arranged at the side 121b of the second device tier 121, e.g., the backside of the second device tier 121. This enables further implementation options for the backside routing of the clock. In implementations comprising the interconnect structure 126 and the interconnect structure 128, the interconnect structure 116 of the first circuit tier 110 may be referred to as a first interconnect structure, the interconnect structure 128 of the second circuit tier 120 may be referred to as a second interconnect structure (“backside interconnect structure”), and the interconnect structure 126 may be referred to as a third interconnect structure (“backside interconnect structure”). The interconnect structure 128 thus refers to an interconnect structure of the second circuit tier 120 arranged at the side 121b of the second device tier 121, while the backside interconnect structure refers to an interconnect structure of the second circuit tier 120 arranged at the frontside 121a of the second device tier 121, i.e., between the first active device tier 111 and the second active device tier 121. In this configuration, a first subset of the clock signal routing interconnects 221 may be comprised in the interconnect structure 128, such that the clock signal may be routed at the backside of the second device tier 121. Further, a second subset of the clock signal routing interconnects 221 may be comprised in the second interconnect structure 126. The first and second subset of clock signal routing interconnects 221 may be connected through the second device tier 121 by TSVs, for example. The second interconnect structure 126 may further comprise the inter-tier interconnects 228.

Having the interconnect structure 126 and the interconnect structure 128 also enables further implementation options for the backside power distribution. For instance, the PDN 230 of FIG. 2 may in this case comprise a first set of power rails arranged in the interconnect structure 128 and configured to supply power to the clock distribution network 220, and further a second set of power rails arranged in the second interconnect structure 126 and configured to supply power to the clocked circuit 210.

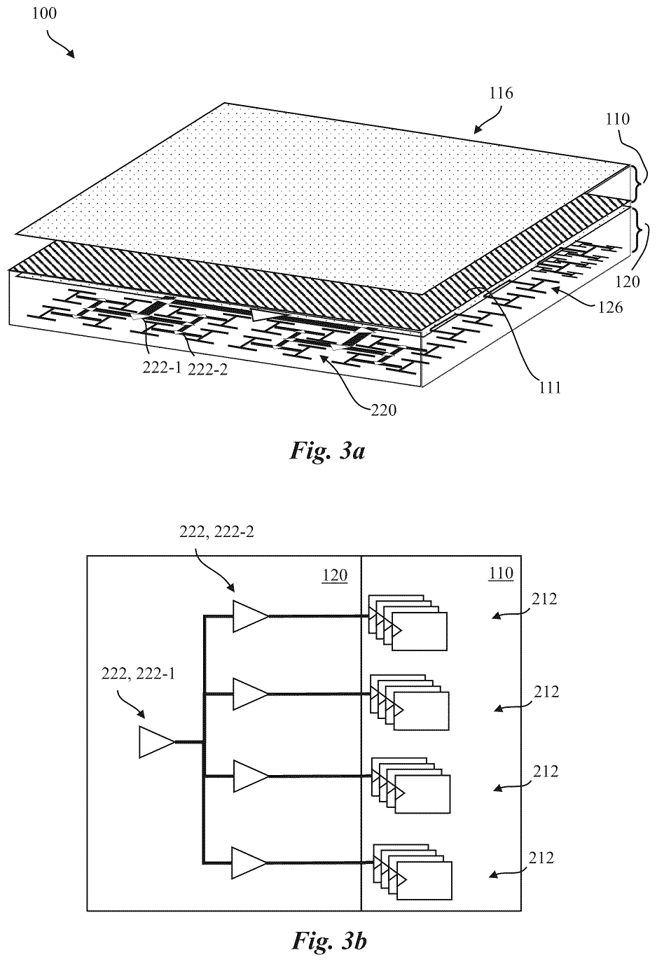

FIG. 3a shows a schematic perspective view of the IC device 100 of FIG. 1 and FIG. 2. FIG. 3b shows a distribution of active clock devices 222 and registers 212 between the first circuit tier 110 and the second circuit tier 120. In FIG. 3a, the clock distribution network 220 is depicted in an H-tree implementation. In FIG. 3b, the active clock devices 222 are exemplified by a first active clock device 222-1 with a fan-out (FO) of FO=4 and connected to a set of second active clock devices 222-2 with a fanout of FO=8 which in turn are connected to a respective set of registers 212 here by way of example depicted as flip-flops. The first active clock devices 222-1 and the second active clock devices 222-2 may for example have a drive strength of 16 and 8, respectively.

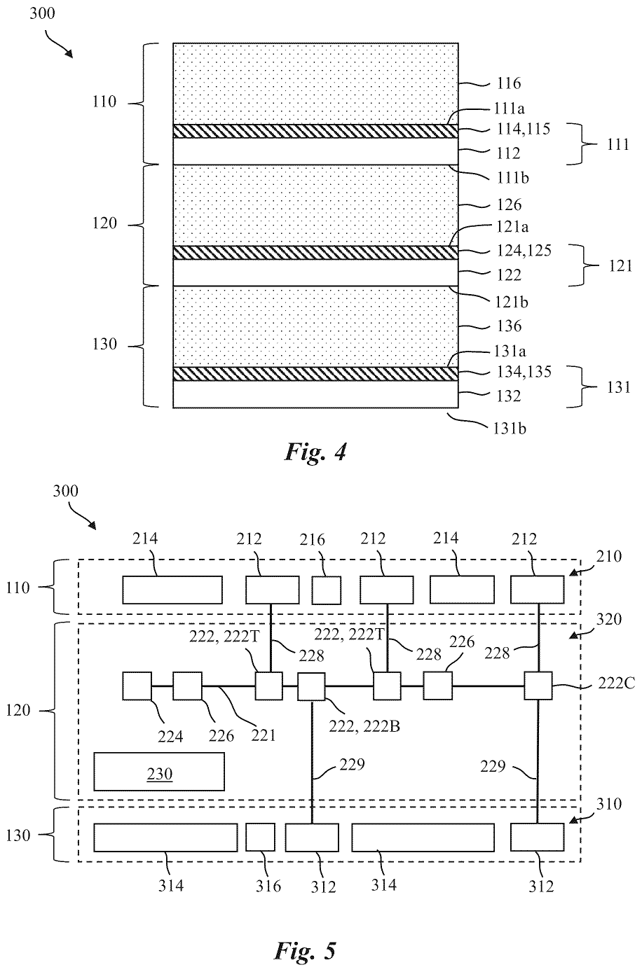

FIG. 4 schematically shows a schematic cross-section of a further IC device 300 in accordance with some embodiments of the present disclosure. The IC device 300 comprises, like the IC device 100 of FIG. 1, a stack of circuit tiers including a first circuit tier 110 and a second circuit tier 120. The first circuit tier 110 and the second circuit tier 120 of the IC device 300 generally correspond to the first circuit tier 110 and the second circuit tier 120 of the IC device 100 of FIG. 1. Hence, to avoid undue repetition, for a description of the features of the first circuit tier 110 and the second circuit tier 120 of the IC device 300, reference is made to the discussion of the correspondingly numbered features in FIG. 1.

The IC device 300 differs from the IC device 100 by further comprising a third circuit tier 130. The third circuit tier 130 generally corresponds to the first circuit tier 110 and comprises a third device tier 131 comprising a third set of active devices 135. The third device tier 131 may as shown, in analogy with the first device tier 111, comprise a substrate 132 and a FEOL structure 134 arranged or formed on the substrate 132 and comprising the third set of active devices 135. The third set of active devices 135 may thus be referred to as frontend transistors of the FEOL structure 134. The first circuit tier 110, the second circuit tier 120, and the third circuit tier 130 may, analogous to the discussion of the first circuit tier 110 and the second circuit tier 120 of the IC device 100 of FIG. 1, correspond to a first, second, and third die, arranged to form a stack of dies. Additionally, as described with reference to the second device tier 121 of the IC device 100, the substrate 132 of the third device tier 131 need not be present, if removed by substrate thinning during device fabrication.

The third circuit tier 130 further comprises a third BEOL interconnect structure 136. The third interconnect structure 136 is arranged at a first side 131a of the third device tier 131. The first side 131a is as shown the side of the third device tier 131 facing away from the third device tier 131. In the illustrated example, the first side 131a defines a frontside of the FEOL structure 134 and the third device tier 131. Thus, with respect to the FEOL structure 134 and the third device tier 131, the third interconnect structure 136 may be referred to as a (third) frontside interconnect structure. The third interconnect structure 136 is configured to interconnect the third set of active devices 135, in particular to implement a further clocked circuit 310 of the third circuit tier 130 further described below with reference to FIG. 5.

Similar to the preceding discussion of the first circuit tier 110 and the second circuit tier 120 of the IC device 100 of FIG. 1, the illustrated partitioning of the IC device 300 into the first circuit tier 110, the second circuit tier 120, and the third circuit tier 130 may, but need not, correspond to an actual structural and/or manufacturing-related partitioning of the IC device 300. For example, where the IC device 300 comprises a stack of dies, the first circuit tier 110, the second circuit tier 120, and the third circuit tier 130 may correspond respectively to a first, second and third die. Thus, the first device tier 111 may be a device tier of the first die, and the first interconnect structure 116 may be a frontside interconnect structure of the first die. The second device tier 121 may be a device tier of the second die, and the second interconnect structure 126 may be a frontside interconnect structure of the second die. The third device tier 131 may be a device tier of the third die, and the third interconnect structure 136 may be a frontside interconnect structure of the third die. The first circuit tier 110, the second circuit tier 120, and the third circuit tier 130 may thus be fabricated on respective wafers, and subsequently be stacked and bonded with the second interconnect structure 126 facing the second side 111b of the first die (i.e., face-to-back), and the third interconnect structure 136 facing the backside 121b of the second die. Thus, while the second interconnect structure 126 and the third interconnect structures 136 in this example are fabricated at a respective frontside of the second and third dies, respectively, they may after stacking and bonding define backside interconnect structures with respect to the first die. However, analogous to the preceding discussion of the IC device 100, other fabrication approaches are also possible. For instance, a first portion (i.e., a first subset of interconnect layers) of the third interconnect structure 136 may be formed during backside processing of the second die/wafer and a second portion (i.e., a second subset of interconnect layers) of the third interconnect structure 136 may be formed during frontside processing of the third die/wafer. In this case, the third interconnect structure 136 may be formed during bonding of the second and third dies/wafers, by bonding the first and second portions of the third interconnect structure 136, thereby forming a common/composite third interconnect structure defining a backside interconnect structure with respect to the first and second dies. As another example, the third interconnect structure 136 may be formed during backside processing of the second die/wafer and subsequently the second and third dies may be bonded with the third interconnect structure 136 to the third device tier 131 of the third die. As another example, while in FIG. 4 the side 131a of the third device tier 131 is facing the first device tier 111 and the second device tier 121, an opposite orientation is also possible. That is, in an unillustrated example, the third device tier 131 may be arranged with its backside 131b facing the facing the first device tier 111 and the second device tiers 121. The third interconnect structure 136 may in this case define a backside interconnect structure also with respect to the third device tier 131. In this case, the third circuit tier 130 may typically comprise a further frontside interconnect structure arranged at the side 131a of the third device tier 131 and configured to interconnect the third set of active devices 135, e.g., to implement the second clocked circuit 310.

FIG. 5 is a schematic block diagram showing in a schematic manner a circuit configuration of the 3D IC device 300. As shown in FIG. 5, the IC device 300 comprises a first clocked circuit 210 comprised in the first circuit tier 110, a second clocked circuit 310 comprised in the third circuit tier 130, and a clock distribution network 320. In the illustrated example, the clock distribution network 320 is comprised in both the second circuit tier 120 and the third circuit tier 130 as further described in the following.

The first clocked circuit 210 corresponds to the clocked circuit 210 of the IC device 100 of FIG. 2. The second clocked circuit 310, like the first clocked circuit 210, comprises registers 312, circuit blocks 314, and circuit blocks 316, at least some of which are synchronous circuits clocked by the clock distribution network 320. Each of the registers 312, the circuit blocks 314, and the circuit blocks 316 comprise third active devices (transistors) comprised in the third set of active devices 135 of the third device tier 131. That is, the third active devices refers to any active devices/transistors (typically a subset) of the third device tier 131 (e.g., the FEOL structure 134) comprised in the second clocked circuit 310. For ease of explanation, the same reference signs may in the following be used to refer to respective circuit blocks of the second clocked circuit 310 and the third active devices comprised in/implementing the respective circuit blocks. The second clocked circuit 310 may, like the first clocked circuit 210, comprise a set of clock inputs, each connected to a clock output of the clock distribution network 320 to receive the clock signal from the clock distribution network 320. Each clock input may be connected to a respective synchronous circuit portion or circuit block of the clocked circuit 310. The clocked circuit 310 may include various combinations of registers, macros, IP blocks, and/or non-IP blocks, each implemented by a respective subset of the third set of active devices 135 of the third device tier 131. For example, the circuit blocks 314 may represent any one of a macro, an IP block, or a non-IP blocks. The circuit block 316 may represent a combinational logic circuit block. Each register 312 may comprise flip-flops and/or latches. Each register 312 may comprise one or more clock inputs, each connected to a corresponding clock output of the clock distribution network 320. While not expressly shown in FIG. 5, the registers 312 may be connected to other circuit blocks 314 or circuit blocks 316 of the second clocked circuit 310, to receive, store, and supply data processed by the second clocked circuit 310.

The clock distribution network 320 generally corresponds to the clock distribution network 220 of the IC device 100, and accordingly comprises a set of active clock devices such as active clock devices 222, active clock devices 224, and/or active clock devices 226 in the form of clock drivers/repeaters/gates/balancing buffers. The active clock devices 222, the active clock devices 224, and/or the active clock devices 226 are formed by second active devices (transistors) comprised in the second set of active devices 125 of the second device tier 121. The clock distribution network 320 further comprises clock signal routing interconnects 221. The clock signal routing interconnects 221 may comprise a first and second subset of clock signal routing interconnects 221 comprised in the second interconnect structure 126 of the second circuit tier 120 and the third interconnect structure 136 of the third circuit tier 130, respectively. The clock distribution network 320 further comprises first inter-tier interconnects 228 and the second inter-tier interconnects 229. The first inter-tier interconnects 228 are comprised in the second interconnect structure 126 and connected to the first clocked circuit 210 of the first circuit tier 110 for vertically routing the clock signal between the first circuit tier 110 and the second circuit tier 120. The second inter-tier interconnects 229 are comprised in the third interconnect structure 136 and connected to the second clocked circuit 310 of the third circuit tier 130 for vertically routing the clock signal between the second circuit tier 120 and the third circuit tier 130.

In particular, the clock distribution network 320 may comprise first active clock devices 222T connected to clock inputs of registers 212 of the first circuit tier 110. The clock distribution network 320 may further comprise second active clock devices 222B connected to clock inputs of registers 312 of the third circuit tier 130. The clock distribution network 320 may further comprise third active clock devices 222C connected both to clock inputs of registers 212 of the first circuit tier 110, and to clock inputs of registers 312 of the third circuit tier 130.

The clock distribution network 320 may further, like the clock distribution network 220 of the IC device 100, be co-integrated with a PDN 230 in the second circuit tier 120 and the second interconnect structure 126.

Accordingly, as demonstrated by FIG. 5, in accordance with some implementations of the present disclosure, a clock distribution network 320 and, optionally, the PDN 230, may be shared by the clocked circuit 210 and a clock distribution network 220 of the first circuit tier 110 and the second circuit tier 120.

The person skilled in the art realizes that the present disclosure by no means is limited to the examples described above. On the contrary, many modifications and variations are possible within the scope of the appended claims. For example, in the illustrated examples discussed above, each of the active clock devices, including clock drivers, clock repeaters, clock gates, and/or input/output/balancing clock buffers of the clock distribution network 220 and/or the clock distribution network 320 are implemented by active devices of the second device tier 121. However, it is also possible to distribute the active clock devices of the clock distribution network 220 and/or the clock distribution network 320 between the different circuit tiers (for clock distribution network 220 between the circuit tiers 110 and the circuit tier 120, and for clock distribution network 320 between the circuit tier 110, the circuit tier 120, and the circuit tier 130). Thus, only some of the active clock devices of the clock distribution network 220 and/or the clock distribution network 320 may be implemented by the second set of active devices 125 of the second device tier 121, and the other active clock devices may be implemented by the first set of active devices 115 and/or the third set of active devices 135 of the first device tier 111 and/or the third device tier 131. In general, it may be beneficial to implement at least the clock buffers (input/output/balancing) of the clock distribution network 220 and/or the clock distribution network 320 by the second set of active devices 125 of the second device tier 121. This since, the above-discussed benefit of facilitating clock tree balancing may be maintained. Additionally, since the connections between active clock devices 222 and the registers 212 and/or the registers 312 typically outnumber the connections to the clock drivers or clock gates, it is contemplated this may further provide the greatest contribution to a reduced area penalty of backside routing of the clock.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A device comprising:
a first device tier comprising a first set of active devices;
a second device tier comprising a second set of active devices;
an interconnect structure;
a clocked circuit comprising first active devices of the first set of active devices; and
a clock distribution network comprising clock signal routing interconnects arranged in the interconnect structure, and a set of active clock devices formed by second active devices comprised of the second set of active devices,
wherein the clocked circuit is connected to the clock distribution network to receive a clock signal.

2. The device of claim 1, wherein the interconnect structure is arranged at a side of the first device tier facing the second device tier.

3. The device according to claim 1, wherein the set of active clock devices comprises clock buffers.

4. The device according to claim 1, wherein the set of active clock devices comprises one or more active clock devices located within a footprint of a circuit block being any one of a register, a macro, an IP block, or a non-IP block, and comprising active devices of the first device tier.

5. The device according to claim 1, wherein the clocked circuit comprises a set of clock inputs each connected to an output of a respective active clock device of the set of active clock devices to receive the clock signal from the clock distribution network.

6. The device according to claim 5, wherein the clocked circuit comprises a set of registers, wherein the set of clock inputs comprise clock inputs of the set of registers.

7. The device according to claim 1,
wherein the set of active clock devices comprises clock buffers,
wherein the clocked circuit comprises a set of registers comprising a set of clock inputs connected respectively to outputs of the clock buffers to receive the clock signal from the clock distribution network, and
wherein each of the clock buffers is located within a footprint of a respective register.

8. The device according to claim 7, wherein the registers each comprise a flip-flop.

9. The device according to claim 7, wherein the registers each comprise a latch.

10. The device according to claim 1, wherein the clock distribution network comprises a clock tree.

11. The device according to claim 1, further comprising a power distribution network arranged in the interconnect structure and configured to supply power to the clocked circuit and the clock distribution network.

12. The device according to claim 1, wherein the interconnect structure is a first interconnect structure, the device further comprising a second interconnect structure arranged at a side of the first device tier facing away from the second device tier and configured to interconnect the first set of active devices.

13. The device according to claim 12, wherein the first interconnect structure is arranged at a side of the second device tier facing the first device tier.

14. The device according to claim 12, wherein the first interconnect structure is arranged at a side of the second device tier facing away from the first device tier, and
wherein the device further comprises a third interconnect structure arranged at the side of the second device tier facing the first device tier and configured to interconnect the second set of active devices.

15. The device according to claim 1, further comprising a third device tier comprising a third set of active devices, wherein the clocked circuit is a first clocked circuit, and the device further comprises a second clocked circuit comprising third active devices of the third set of active devices.

16. The device of claim 15, wherein the second clocked circuit is connected to the clock distribution network to receive a clock signal.

17. The device according to claim 15, wherein the second clocked circuit comprises a set of clock inputs each connected to an output of a respective active clock device of the set of active clock devices to receive the clock signal from the clock distribution network.

18. The device according to claim 1, further comprising a first front-end-of-line (FEOL) structure of a first die, the first FEOL structure including the first set of active devices, wherein the first FEOL structure is arranged at a frontside of the first die, and wherein the interconnect structure and the second device tier are arranged at a backside of the first die, opposite the frontside of the first die.

19. The device according to claim 18, further comprising a second FEOL structure of a second die, the second FEOL structure comprising the second set of active devices.

20. The device of claim 1, wherein the second set of active devices are backend transistors arranged in the interconnect structure.
